(19) United States
(12) Patent Application Publication
(10) Pub. No.: US 2024/0156079 A1
(43) Pub. Date: May 16, 2024

(54) SYSTEMS AND METHODS FOR COOLING SENSOR PACKAGES

(71) Applicant: MINERAL EARTH SCIENCES LLC, MOUNTAIN VIEW, CA (US)

(72) Inventors: Gabriella Levine, San Francisco, CA (US); Erich Schlaepfer, Sunnyvale, CA (US)

(21) Appl. No.: 18/055,661

(22) Filed: Nov. 15, 2022

(51) Int. Cl. A01M 7/00; A01G 25/09; G01D 11/30; H05K 7/20

(52) U.S. Cl. CPC A01M 7/0089; A01G 25/09; A01M 7/0042; G01D 11/30; H05K 7/2039

(57) ABSTRACT

Implementations are disclosed for a kit for mounting a sensor package to agricultural equipment, robot, etc. In various implementations, the kit includes: a reusable, compressible heat transfer member configured to transfer heat from the sensor package to a thermally conductive surface of the agricultural equipment and a compressive interface configured to couple the sensor package to the agricultural equipment and compress the reusable, compressible heat transfer member between the sensor package and the thermally conductive surface of the agricultural equipment. Manipulating the compressive interface to compress the reusable, compressible heat transfer member between the sensor package and the thermally conductive surface of the agricultural vehicle causes heat to be transferred from the sensor package through the reusable, compressible heat transfer member to the thermally conductive surface causing heat to be transferred from the sensor package through the reusable, compressible heat transfer member to the thermally conductive surface for dissipation.

### BACKGROUND

Precision agriculture is becoming increasingly commonplace due to the advancement of various different technologies, such as agricultural robots and rovers, to name a few. These technologies enable the capture of enormous amounts of agricultural sensor data—particularly high-resolution imagery—at close range. These agricultural sensor data can then be processed by a variety of different agricultural tasks to make decisions on the scale of individual plants, or even constituent parts of plants. For example, high-resolution imagery may be processed using machine learning models to generate various agricultural inferences that can be the basis for targeted agricultural decision making.

In some implementations, sensor-equipped modular edge computing devices (also referred to as “edge compute nodes” or “edge sensor packages”) may be mountable on various agricultural vehicles such as tractors, boom, pivots, irrigation systems, etc. One challenge with these sensor packages is their proclivity to overheat, which may be especially true when the sensor packages are disposed on various pieces of agricultural equipment that may be exposed to harsh environmental conditions, including heat and sunlight. Furthermore, it may not be desirable to include active cooling mechanisms (such as fans) as a part of the sensor packages, as they may increase the size, mass, and/or complexity of the sensor package.

### SUMMARY

Implementations are described herein of a reusable, compressible, heat transfer member (e.g., material) that allows for increased heat transfer away from these sensor packages (which, in some instances, may be constructed of a metal) to the agricultural device itself (which, in some instances, may also be constructed of a metal). A sensor package including one or more sensors and/or one or more processors may be in direct or indirect contact with a portion of the agricultural device (e.g., along a boom affixed to a tractor, along a center pivot deployed in a field, or the like). Portion(s) of the sensor packages (e.g., their processors) may be disposed in thermal contact with the agricultural device through a reusable, compressible heat transfer material. A compressible interface may be used to couple the sensor package to the agricultural device and compress the reusable, compressible heat transfer material. The compression may, in some implementations, allow the reusable, compressible heat transfer material to conform to the shape of the agricultural device on which it is placed. Further, this compression may increase the surface area of the reusable, compressible heat transfer material and/or the contact area of the reusable, compressible heat transfer material and the agricultural device, thus increasing the capacity to transfer and ultimately, dissipate heat.

The reusable, compressible heat transfer member is a heat conductive material. In some instances, the reusable, compressible heat transfer member is a thermal interface material. The reusable, compressible heat transfer member may be bronze, phosphor bronze, copper, silver, aluminum, brass, a combination thereof, or any other heat transferring material. In some implementations, the reusable, compressible heat transfer member may be in the form of a “wool” (e.g., a copper wool) or a fabric. If the sensor package needs to be removed from the agricultural device, the heat transfer member may be removed and reused without use of any additional materials.

In some implementations, the compressible interface includes one or more spring fingers or a clamp. In some further implementations, the clamp may additionally include a first and a second part, for example a hose clamp or a pipe clamp. The two portions of the clamp may collectively circumscribe the agricultural device. In some instances, the reusable, compressible heat transfer member may be placed between the at least one portion of the clamp and the agricultural device to transfer heat from the sensor package to the agricultural device. In some implementations, the compressible interface may include one or more protrusions, barbs, or other piercing arms that may embed or pierce into an exterior surface of the agricultural device in order to facilitate heat transfer. In still other implementations, the compressible interface may be finned. The heat transfer member may then be compressed into the fins to increase the surface area available for heat transfer.

In one aspect, a kit for mounting a sensor package equipped with one or more processors to agricultural equipment may include: a reusable, compressible heat transfer member configured to transfer heat from the sensor package to a thermally conductive surface of the agricultural equipment; and a compressive interface configured to couple the sensor package to the agricultural equipment and compress the reusable, compressible heat transfer member between the sensor package and the thermally conductive surface of the agricultural equipment; where manipulating the compressive interface to compress the reusable, compressible heat transfer member between the sensor package and the thermally conductive surface of the agricultural equipment causes heat to be transferred from the sensor package through the reusable, compressible heat transfer member to the thermally conductive surface that causes heat to be transferred from the sensor package through the reusable, compressible heat transfer member to the thermally conductive surface for dissipation.

In some implementations, the reusable, compressible heat transfer member is selected from a material consisting of: bronze, phosphor bronze, copper, silver, aluminum, and brass. In some implementations, the reusable, compressible heat transfer member is secured to and conforms to a shape of the sensor package.

In some implementations, the compressive interface includes one or more spring fingers. In other implementations, the compressive interface comprises a clamp or a strap. In some such implementations, the clamp further includes a first part and a second part; wherein the first part and the second part are configured to collectively circumscribe the thermally conductive surface of the agricultural equipment; and wherein the reusable, compressible heat transfer member is disposed between the first part or the second part and the thermally conductive surface when in use. In still other implementations, the compressive interface comprises one or more protrusions configured to pierce an exterior surface of the thermally conductive surface of the agricultural equipment. In still yet other implementations, the compressive interface includes a plurality of fins and the heat transfer member is compressed into the plurality of fins.

In some implementations, the thermally conductive surface is a surface of an irrigation boom.

In another aspect, a sensor package includes: an exterior surface configured to contact a thermally conductive surface of an agricultural vehicle or accessory equipment (i.e., a spray boom, mount, etc.); a processor; where at least a portion of the exterior surface of the sensor package is configured to contact a compressive interface to compress a reusable, compressible heat transfer member between the sensor package and the thermally conductive surface of the agricultural vehicle which causes heat to be transferred from the sensor package through the reusable, compressible heat transfer member to the thermally conductive surface that causes heat to be transferred from the sensor package through the reusable, compressible heat transfer member to the thermally conductive surface for dissipation a thermally conductive surface of the agricultural vehicle.

In some implementations, the reusable, compressible heat transfer member is secured to and conforms to a shape of the sensor package.

In some implementations, the reusable, compressible heat transfer member is selected from a material consisting of: bronze, phosphor bronze, copper, silver, aluminum, and brass. In other implementations, the reusable, compressible heat transfer member may not be a metal, and may, for example, be a liquid.

In some implementations, the compressive interface includes one or more spring fingers. In other implementations, the compressive interface comprises a clamp or a strap. In some such implementations, the clamp further includes a first part and a second part; where the first part and the second part are configured to collectively circumscribe the thermally conductive surface of the agricultural vehicle; and where the reusable, compressible heat transfer member is disposed between the first part or the second part and the thermally conductive surface when in use. In other implementations, the compressive interface comprises one or more protrusions configured to pierce an exterior surface of the thermally conductive surface of the agricultural equipment. In still other implementations, the compressive interface includes a plurality of fins and the heat transfer member is compressed into the plurality of fins.

In addition, some implementations include methods for using kits and/or sensor packages configured with selected aspects of the present disclosure to transfer heat from sensor package(s) to agricultural device(s) and/or vehicle(s) to which the sensor package(s) are mounted. For example, a method for using a kit to mount a sensor package equipped with one or more processors to agricultural equipment may include: providing a reusable, compressible heat transfer member configured to transfer heat from the sensor package to a thermally conductive surface of the agricultural equipment; and manipulating a compressive interface configured to couple the sensor package to the agricultural equipment to compress the reusable, compressible heat transfer member between the sensor package and the thermally conductive surface of the agricultural equipment; wherein manipulating the compressive interface to compress the reusable, compressible heat transfer member between the sensor package and the thermally conductive surface of the agricultural equipment causes heat to be transferred from the sensor package through the reusable, compressible heat transfer member to the thermally conductive surface for dissipation.

In some implementations, the method may further comprise adjusting an amount of compression provided by the compressive interface. In some implementations, the reusable, compressible heat transfer member is selected from a material consisting of: bronze, phosphor bronze, copper, silver, aluminum, and brass.

It should be appreciated that all combinations of the foregoing concepts and additional concepts described in greater detail herein are contemplated as being part of the subject matter disclosed herein. For example, all combinations of claimed subject matter appearing at the end of this disclosure are contemplated as being part of the subject matter disclosed herein.

### BRIEF DESCRIPTION OF THE DRAWINGS

FIG. 1 schematically depicts an example environment in which disclosed techniques may be employed in accordance with various implementations.

FIG. 2 depicts an example of how sensor packages may be deployed on an exemplary piece of agricultural equipment.

FIG. 3 depicts a detailed example of how a reusable, compressible heat transfer member transfer heat from a sensor package to a thermally conductive surface of the agricultural equipment.

FIGS. 4A, FIG. 4B, FIG. 4C, and FIG. 4D depict cross-sectional views of the example of FIG. 3 with a compressive interface, in accordance with various implementations described herein. FIG. 4A depicts a cross-sectional view of the example of FIG. 3 where the compressive interface is a clamp. FIG. 4B depicts a cross-sectional view of the example of FIG. 3 where the compressive interface includes a spring finger. FIG. 4C depicts a cross-sectional view of the example of FIG. 3 where the compressive interface includes one or more protrusions to pierce an exterior surface of the thermally conductive surface. FIG. 4D depicts a cross-sectional view of the example of FIG. 3 where the compressive interface includes a plurality of fins.

FIG. 5 depicts an example of how heat is transferred between a sensor package and a reusable, compressible heat transfer member.

FIG. 6 schematically depicts an example method for using components configured with selected aspects of the present disclosure.

### DETAILED DESCRIPTION

Implementations are described herein for transferring heat from a sensor package to a thermally conductive surface of a piece of agricultural equipment, robot, etc. More particularly, but not exclusively, a sensor package may be in direct or indirect contact with a portion of a thermally conductive surface of an agricultural device, robot, or other vehicle. A compressible interface may be used to couple the sensor package to the agricultural device and compress a reusable, compressible heat transfer material to transfer and ultimately, dissipate heat from the sensor package.

Implementations are disclosed for a kit for mounting a sensor package to an agricultural device, robot, etc. In various implementations, the kit includes: a reusable, compressible heat transfer member configured to transfer heat from the sensor package to a thermally conductive surface of the agricultural equipment and a compressive interface configured to couple the sensor package to the agricultural equipment and compress the reusable, compressible heat transfer member between the sensor package and the thermally conductive surface of the agricultural equipment. Manipulating the compressive interface to compress the reusable, compressible heat transfer member between the sensor package and the thermally conductive surface of the agricultural vehicle causes heat to be transferred from the sensor package through the reusable, compressible heat transfer member to the thermally conductive surface causing heat to be transferred from the sensor package through the reusable, compressible heat transfer member to the thermally conductive surface for dissipation.

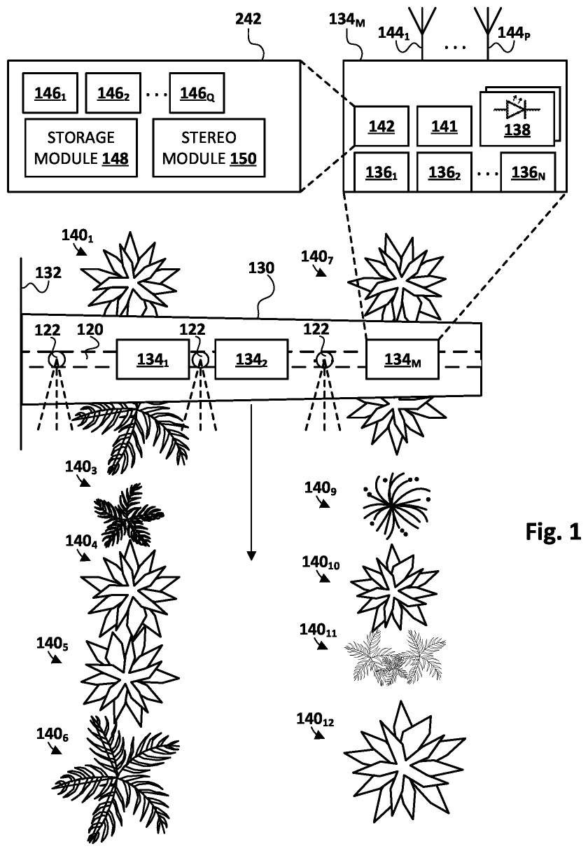

FIG. 1 depicts an example field of plants 140₁₋₁₂. An agricultural boom 130 mounted to a vehicle 132 (mostly not visible in FIG. 1, e.g., a tractor, a robot, a truck, motor bike etc.) is being carried over plants 140₁₋₁₂ as shown by the arrow to perform agricultural tasks and/or to gather sensor data. Boom 130 may include, for instance, a conduit 120 with one or more sprayers 122 or sprinklers for irrigation, sprayers for chemical application, etc. Also mounted on boom 130 are a plurality of sensor packages 134_{1-M} according to selected aspects of the present disclosure. Although shown as boxes on top of the conduit 120 of the boom 130 in FIG. 1, the sensor packages 134_{1-M} may alternatively be mounted along the conduit 120 at other locations of boom 130 or in other locations on the agricultural device. Furthermore, while multiple sensor packages 134_{1-M} are depicted in FIG. 1, any number of sensor packages 134, including a single sensor package 134, may be deployed in similar fashions.

As shown by the called-out window at top right, sensor package 134_{M} may, in some implementations, include one or more sensors in the form of vision sensors 136_{1-N}, one or more lights 138, a light controller 141, and processor 142 that is configured to carry out selected aspects of the present disclosure. Such components, in particular light(s) 138, may produce heat that may contribute a sensor package's proclivity to overheat. Other sensor packages may or may not be similarly configured. Vision sensors 136_{1-N} may take various forms and may or may not be the same as each other. These forms may include, for instance, an RGB digital camera, a stereoscopic camera, an infrared camera, a 1.5D camera, a 3D camera, a light detection and ranging (LIDAR) sensor, and so forth.

The sensor package 134_{M} may also include one or more wireless antenna 144₁₋ₚ. In some implementations, each wireless antenna 144 may be configured to transmit and/or receive different types of wireless data. For example, where a temperature sensor (not illustrated in FIG. 1) is included within the sensor package 134_{M}. a first antenna 144₁ may be configured to transmit and/or receive wireless temperature data, e.g., for purposes such as determining if a sensor package 134_{M} may be overheating. Another antenna 144ₚ may be configured to transmit and/or receive IEEE 802.12 family of protocols (Wi-Fi) or Long-Term Evolution (LTE) data. Another antenna 144 may be configured to transmit and/or receive 5G data. Any number of antennas 144 may be provided to accommodate any number of wireless technologies.

Processor 142 may include various types of circuitry (e.g. FPGA, ASIC) that is configured to carry out various agricultural tasks. For example, and as shown in the called-out window at top left in FIG. 1, processor 142 may include any number of tensor processing units (TPU) 146_{1-Q}, a storage module 148, and a stereo module 150 (one or more graphical process units (GPU) and/or central processing units (CPU) may also be present, even if not depicted). In some implementations, four TPUs 146₁₋₄ may be employed to process sensor data, e.g., in parallel, using one or more various machine learning models, e.g., at an inference frame rate per model of 10 FPS or greater. Storage module 148 may be configured to acquire and store, e.g., in various types of memories onboard sensor package 134, sensor data acquired from one or more sensors (e.g., vision sensors 136_{1-N}). This processing may be computationally intense, and consequently, may increase a temperature of processor 142 (and in some cases, the entire sensor package 134).

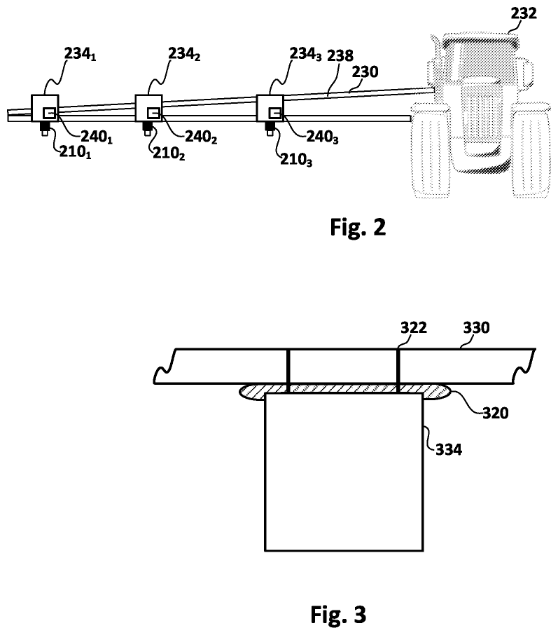

FIG. 2 depicts another example of how sensor packages may be arranged and/or deployed on a vehicle or accessory equipment to a vehicle, for example a tractor 232 equipped with a boom sprayer 230. Although illustrated as being on a tractor 232, this is not intended to be limiting as the vehicle may be any type of vehicle, including non-agricultural vehicles (e.g., electric vehicles, robots, or the like). Now returning to the implementation illustrated in FIG. 2, the boom sprayer 230 may additionally include a plurality of sprayers 210₁₋₃, to dispense water, liquid herbicides or pesticides, etc. over a target (e.g., a field of plants). In some implementations, portion(s) of the sensor packages 234₁₋₃ (e.g., their processors) may be disposed in contact with a reusable, compressible heat transfer member (see 320 in FIGS. 3-5). Often, but not exclusively, the boom sprayer 230 and/or conduit 238 (or other point of attachment) may be constructed of metal or other thermally conductive material. In some such implementations, reusable, compressible heat transfer members (see 320 in FIGS. 3-5) are disposed between the respective sensor package(s) 234₁₋₃ and the boom sprayer 230 and/or conduit 238 (or any other thermally conductive surface), which causes heat to be transferred from the sensor package(s) 234₁₋₃ through the reusable, compressible heat transfer members (see 320 in FIGS. 3-5) to the boom sprayer 230 and/or conduit 238 (or other thermally conductive surface) for dissipation, for example into the surrounding environment.

Although illustrated in FIG. 2 as having an equal number of sprayers 210₁₋₃ and sensor packages 234₁₋₃ spaced similarly across boom sprayer 230, this is not to be understood at limiting. In other implementations, the sensor packages 234 may not coincide spatially with sprayers 210 or other aspects of the agricultural equipment. Furthermore, the illustrated number of sensor packages 234 is also not intended to be limiting. The location, spacing, and/or number of sensor packages 234 may be determined by the particular sensors contained in the sensor packages 234 and/or the resulting use thereof.

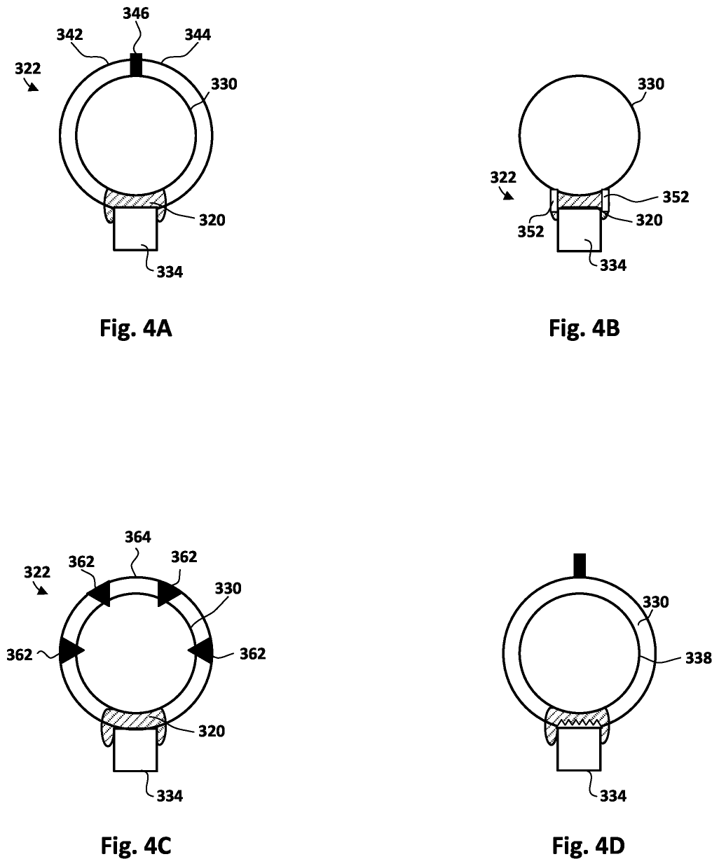

Turning now to FIGS. 3, 4A-D, and 5, exemplary implementations of a reusable, compressible heat transfer member 320 and sensor package 334 are illustrated. With respect to the implementation illustrated in FIG. 3, the sensor package 334 (with one or more processors) is mounted onto a piece of agricultural equipment (for example the boom sprayer 230 illustrated in FIG. 2), or another vehicle (e.g., an electric car, robotic vehicle, or the like). The reusable, compressible heat transfer member 320 is able to transfer heat from the sensor package to a thermally conductive surface 330 (e.g., of the agricultural equipment). In some implementations, the reusable, compressible heat transfer member 320 may be constructed of bronze, phosphor bronze, copper, silver, aluminum, brass, or any combination thereof. However, these materials are not to be understood as limiting as any heat transferrable material may be used.

In some implementations, the reusable, compressible heat transfer member 320 may be in the form of a “wool” (e.g., such as a copper wool, silver wool, brass wool, or the like). Such a “wool” may be a bundle of fine and flexible filaments, which when compressed may increase the surface area. Additionally, this “wool” may allow for the heat transfer material to be both reusable and compressible. In other implementations, the reusable, compressible heat transfer member 320 may be in the form of a fabric. In still other implementations, the reusable, compressible heat transfer member is a non-metal material, for example a liquid.

A compressive interface 322 can be used to couple the sensor package 334 to the thermally conductive surface 330 (e.g., of the agricultural equipment). This compressive interface can compress the reusable, compressible heat transfer member 320 between the sensor package 334 and the thermally conductive surface 330. The compressive force caused by the compressive interface 322 when in use may, in some implementations, allow the reusable, compressible heat transfer material 320 to conform to the shape of the thermally conductive surface 330 on which it is placed. This compression may also increase the surface area of the reusable, compressible heat transfer material 320 and/or the contact area of the reusable, compressible heat transfer material and the thermally conductive surface 330, thus increasing the capacity to transfer and ultimately, dissipate heat generated by the sensor package 334.

A compressive interface 322 can be in a variety of forms. For example, in the implementation illustrated in FIG. 3, the compressive interface 322 is in the form of a strap or a camp. However, FIGS. 4A-D, which are cross-sectional views of a compressive interface 322 coupling a sensor package 334 to the thermally conductive surface 330 (e.g., of the agricultural equipment), illustrate other implementations of compressive interfaces 322.

For example, the compressive interface 322 of FIG. 4A is another implementation of a clamp, where the clamp includes a first part 342 and a second part 344. Similar to the implementation illustrated in FIG. 3, the first part 342 and second part 344 of agricultural the clamp collectively circumscribe the thermally conductive surface 330 (such as the boom of the vehicle) with the reusable, compressible heat transfer material 320 and the thermally conductive surface 330 located between the first part 342 and second part 344 and the thermally conductive surface 330. Compression of the first part 342 and second part 344 of the clamp around the reusable, compressible heat transfer member 320 may increase the surface area of the reusable, compressible heat transfer member 320, thus allowing for increased heat dissipation to the thermally conductive surface 330. In some implementations, the compressive interface 322 may include a screw 346, toggle, or other tightening mechanism for adjusting the amount of compression provided by the compressive interface 322. While not shown in FIG. 4A, in some implementations, the reusable, compressible heat transfer member 320 may be disposed along at least a portion of the interior surfaces of the first part 342 and the second part 344 that contact thermally conductive surface, including up to the entire interior surfaces of parts 342 and 344.

Turning now to FIG. 4B, the compressive interface 322 includes one or more spring fingers 352. In some implementations, the one or more spring fingers 352 can couple the sensor package 334 to the thermally conductive surface 330 while compressing the reusable, compressible heat transfer member 320 between the sensor package 334 and the thermally conductive service 330. In some implementations, the one or more spring fingers 352 may be constructed of a thermally conductive material, and accordingly may further assist to heat dissipation into the surrounding environment.

Referring now to FIG. 4C, the compressive interface 322 includes one or more protrusions 362 that are configured to “bite” into an exterior surface 364 of the thermally conductive surface 330. These protrusions 362 may, in some implementations, include small blades, barbs, or another piercing arms to bite into the exterior surface 364 or paint layer of the thermally conductive surface 330, which may improve thermal transfer between the reusable, compressible heat transfer member 320 and the thermally conductive surface 330. In some implementations, these protrusions 362 may be constructed of a thermally conductive material, e.g., a similar material as was used to construct the reusable, compressible heat transfer member 320.

FIG. 4D illustrates yet another implementation of the compressive interface 322, for example a finned mount 372, including a plurality of fins 374, which increase the surface area for contact with the reusable, compressible heat transfer member 320, which are compressed into the plurality of fins 374 and the thermally conductive surface 330, which results in the reusable, compressible heat transfer member 320 to be compressed into the fins 374 and conform to the shape of the fins 374.

Although several implementations of the compressive interface 322 are discussed herein, these are not to be understood as limiting, as there may other implementations of a compressive interface known to those of skill in the art.

In instances where a sensor package 234, 334 may need to be removed (e.g., for maintenance, repositioning, replacement, or the like), the heat transfer member 320 may be removed and reused without use of any additional materials.

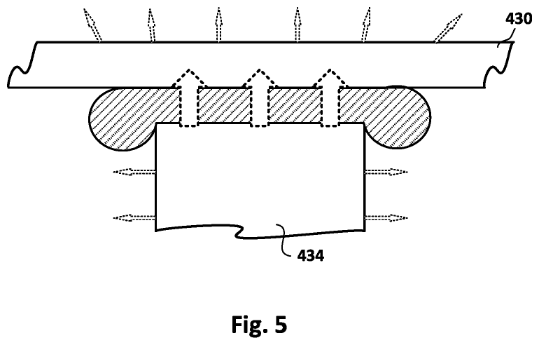

FIG. 5 is an exemplary schematic of how heat may be transferred between a sensor package 534 to a reusable, compressible heat transfer member 520, and ultimately to the thermally conductive surface 530 for dissipation. Generally, heat is generated by the sensor package 534 and some heat may be dissipated into the surrounding environment directly from the sensor package 534 (as illustrated by the smaller broken arrows extending from the sensor package 534). However, most of the heat will be transferred to the reusable, compressible heat transfer member 520 (as illustrated by the large broken arrows extending from the sensor package 534 to the reusable, compressible heat transfer member 520). Heat may then be transferred to the thermally conductive surface 530 and dissipated into the surrounding environment (as illustrated by the medium-sized broken arrows extending from the thermally conductive surface 530).

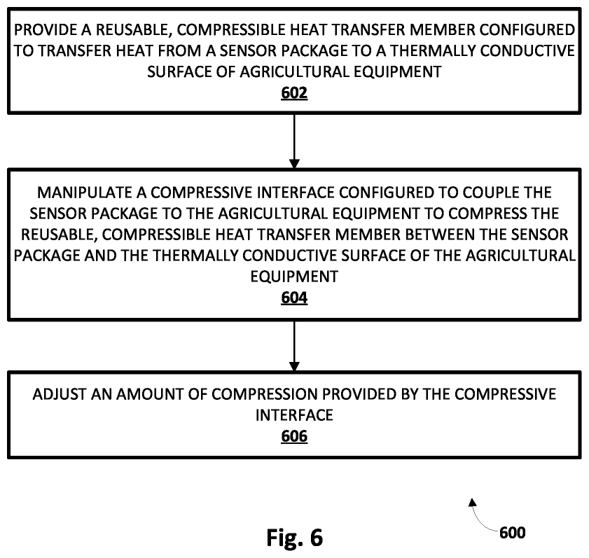

FIG. 6 illustrates a flowchart of an example method 600 of using a sensor package (for example 234₁₋₃ of FIG. 2) to transfer heat from the sensor package to an agricultural device to which the sensor package is mounted. Other implementations may include additional block than those illustrated in FIG. 6 and/or blocks may be performed in a different order and/or in parallel, and/or may omit one or more of the operations of FIG. 6.

At block 602, a reusable, compressible heat transfer member, such as described herein with respect to FIGS. 3, 4A-D, and 5, is provided. This reusable, compressible heat transfer member, as previously described, is configured to transfer heat from the sensor package to a thermally conductive surface of the agricultural equipment (e.g., a boom).

At block 604, a compressive interface is manipulated to couple the sensor package to the agricultural equipment to compress the reusable, compressible heat transfer member between the sensor package and the thermally conductive surface of the agricultural equipment. The compressive interface may be any of the compressive interfaces described herein (see FIGS. 3 and 4A-D) or any others known in the art. Manipulating the compressive interface to compress the reusable, compressible heat transfer member between the sensor package and the thermally conductive surface of the agricultural equipment causes heat to be transferred from the sensor package through the reusable, compressible heat transfer member to the thermally conductive surface for dissipation (as illustrated in FIG. 5).

In some implementations, at block 606, the amount of compression provided by the compressive interface may be adjusted. For example, this may be achieved through the use of a screw, toggle, bolt, or other tightening mechanism (see e.g., FIG. 4A).

While several implementations have been described and illustrated herein, a variety of other means and/or structures for performing the function and/or obtaining the results and/or one or more of the advantages described herein may be utilized, and each of such variations and/or modifications is deemed to be within the scope of the implementations described herein. More generally, all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific implementations described herein. It is, therefore, to be understood that the foregoing implementations are presented by way of example only and that, within the scope of the appended claims and equivalents thereto, implementations may be practiced otherwise than as specifically described and claimed. Implementations of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

What is claimed is:

1. A kit for mounting a sensor package equipped with one or more processors to agricultural equipment, the kit comprising:
a reusable, compressible heat transfer member configured to transfer heat from the sensor package to a thermally conductive surface of the agricultural equipment; and
a compressive interface configured to couple the sensor package to the agricultural equipment and compress the reusable, compressible heat transfer member between the sensor package and the thermally conductive surface of the agricultural equipment;
wherein manipulating the compressive interface to compress the reusable, compressible heat transfer member between the sensor package and the thermally conductive surface of the agricultural equipment causes heat to be transferred from the sensor package through the reusable, compressible heat transfer member to the thermally conductive surface for dissipation.

2. The kit of claim 1, wherein the reusable, compressible heat transfer member is selected from a material consisting of: bronze, phosphor bronze, copper, silver, aluminum, and brass.

3. The kit of claim 1, wherein the reusable, compressible heat transfer member is secured to and conforms to a shape of the sensor package.

4. The kit of claim 1, wherein the compressive interface includes one or more spring fingers.

5. The kit of claim 1, wherein the compressive interface comprises a clamp or a strap.

6. The kit of claim 5, wherein the clamp further includes a first part and a second part;
wherein the first part and the second part are configured to collectively circumscribe the thermally conductive surface of the agricultural equipment; and
wherein the reusable, compressible heat transfer member is disposed between the first part or the second part and the thermally conductive surface when in use.

7. The kit of claim 1, wherein the compressive interface comprises one or more protrusions configured to pierce an exterior surface of the thermally conductive surface of the agricultural equipment.

8. The kit of claim 1, wherein the compressive interface includes a plurality of fins and the heat transfer member is compressed into the plurality of fins.

9. The kit of claim 1, wherein the thermally conductive surface is a surface of an irrigation boom.

10. A sensor package, the sensor package comprising:
an exterior surface configured to contact a thermally conductive surface of an agricultural vehicle;
a processor;
wherein at least a portion of the exterior surface of the sensor package is configured to contact a compressive interface to compress a reusable, compressible heat transfer member between the sensor package and the thermally conductive surface of the agricultural vehicle which causes heat to be transferred from the sensor package through the reusable, compressible heat transfer member to the thermally conductive surface that causes heat to be transferred from the sensor package through the reusable, compressible heat transfer member to the thermally conductive surface for dissipation a thermally conductive surface of the agricultural vehicle.

11. The sensor package of claim 10, wherein the reusable, compressible heat transfer member is secured to and conforms to a shape of the sensor package.

12. The sensor package of claim 10, wherein the reusable, compressible heat transfer member is selected from a material consisting of: bronze, phosphor bronze, copper, silver, aluminum, and brass.

13. The sensor package of claim 10, wherein the compressive interface includes one or more spring fingers.

14. The sensor package of claim 10, wherein the compressive interface comprises a clamp or a strap.

15. The sensor package of claim 14, wherein the clamp further includes a first part and a second part;
wherein the first part and the second part are configured to collectively circumscribe the thermally conductive surface of the agricultural vehicle; and
wherein the reusable, compressible heat transfer member is disposed between the first part or the second part and the thermally conductive surface when in use.

16. The sensor package of claim 10, wherein the compressive interface comprises one or more protrusions configured to pierce an exterior surface of the thermally conductive surface of the agricultural equipment.

17. The sensor package of claim 10, wherein the compressive interface includes a plurality of fins and the heat transfer member is compressed into the plurality of fins.

18. A method of using a sensor package configured to transfer heat from the sensor package to an agricultural device to which the sensor package is mounted, the method comprising:
providing a reusable, compressible heat transfer member configured to transfer heat from the sensor package to a thermally conductive surface of the agricultural equipment; and
manipulating a compressive interface configured to couple the sensor package to the agricultural equipment to compress the reusable, compressible heat transfer member between the sensor package and the thermally conductive surface of the agricultural equipment;
wherein manipulating the compressive interface to compress the reusable, compressible heat transfer member between the sensor package and the thermally conductive surface of the agricultural equipment causes heat to be transferred from the sensor package through the reusable, compressible heat transfer member to the thermally conductive surface for dissipation.

19. The method of claim 18 further comprising adjusting an amount of compression provided by the compressive interface.

20. The method of claim 18, wherein the reusable, compressible heat transfer member is selected from a material consisting of: bronze, phosphor bronze, copper, silver, aluminum, and brass.
